(19) United States
(12) Patent Application Publication
(10) Pub. No.: US 2013/0098435 A1
(43) Pub. Date: Apr. 25, 2013

(54) HYBRID CONTACT FOR AND METHODS OF FORMATION OF PHOTOVOLTAIC DEVICES

(71) Applicants: Zhibo Zhao, Novi, MI (US); Benyamin Buller, Silvania, OH (US); Chungho Lee, San Jose, CA (US); Markus Gloeckler, Perrysburg, OH (US); David Hwang, Perrysburg, OH (US); Scott Mills, Perrysburg, OH (US); Rui Shao, Sylvania, OH (US)

(72) Inventors: Zhibo Zhao, Novi, MI (US); Benyamin Buller, Silvania, OH (US); Chungho Lee, San Jose, CA (US); Markus Gloeckler, Perrysburg, OH (US); David Hwang, Perrysburg, OH (US); Scott Mills, Perrysburg, OH (US); Rui Shao, Sylvania, OH (US)

(73) Assignee: FIRST SOLAR, INC, Perrysburg, OH (US)

(21) Appl. No.: 13/653,938

(22) Filed: Oct. 17, 2012

Related U.S. Application Data
(60) Provisional application No. 61/547,806, filed on Oct. 17, 2011.

(51) Int. Cl. H01L 31/0224; H01L 31/18

(52) U.S. Cl. CPC H01L 31/022466; H01L 31/1884; B82Y 30/00
USPC 136/256; 438/69; 438/98; 977/782

(57) ABSTRACT

Described herein is a contact for a photovoltaic device and method of making the same. The contact has a transparent conductive oxide stack, where a first portion of the transparent conductive oxide stack is formed by atmospheric pressure vapor deposition and a second portion of the transparent conductive oxide stack is formed by physical vapor deposition.

### CLAIM OF PRIORITY

This application claims priority under 35 U.S.C. §119(e) to U.S. Provisional Patent Application Ser. No. 61/547,806 filed on Oct. 17, 2011, which is hereby incorporated by reference in its entirety herein.

### FIELD OF THE INVENTION

Embodiments of the invention relate to the field of photovoltaic devices and more particularly to an electrical contact provided in a photovoltaic device and a manufacturing method thereof.

### BACKGROUND OF THE INVENTION

A photovoltaic device converts the energy of sunlight directly into electricity by the photovoltaic effect. The photovoltaic device can be, for example, a photovoltaic cell, such as a crystalline silicon cell or a thin-film cell. Photovoltaic modules can include a plurality of photovoltaic cells or devices. A photovoltaic device can include multiple layers created on a substrate (or superstrate). For example, a photovoltaic device can include a transparent conductive oxide (TCO) layer, a buffer layer and semiconductor layers formed in a stack on a substrate. The semiconductor layers can include a semiconductor window layer, such as a cadmium sulfide layer, formed on the buffer layer and a semiconductor absorber layer, such as a cadmium telluride layer, formed on the semiconductor window layer. Additionally, each layer can cover all or a portion of the device and/or all or a portion of the layer or substrate underlying the layer. For example, a “layer” can include any amount of any material that contacts all or a portion of a surface.

FIG. 1 is a cross-sectional view of a portion of a photovoltaic device 10 that is often built sequentially on a glass substrate 110, e.g. soda-lime glass. A multi-layered transparent conductive oxide (TCO) stack 150 can be used as a n-type front contact for thin-film photovoltaic devices. The TCO stack 150 has several functional layers including a barrier layer 120, a TCO layer 130 and a buffer layer 140. The front contact can intimately affect various device characteristics such as visual quality, conversion efficiency, stability and reliability. Window layer 160, which is a semiconductor layer, is formed over front contact 150. Absorber layer 170, which is also a semiconductor layer, is formed over window layer 160. Window layer 160 and absorber layer 170 can include, for example, a binary semiconductor such as group II-VI or III-V semiconductors, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InS, InN, InP, InAs, InSb, TlN, TlP, TlAs, TlSb or mixtures thereof. An example of a window layer and absorbing layer can be a layer of CdS and a layer of CdTe, respectively. Back contact 180 is formed over absorber layer 170. Back contact 180 may also be a multi-layered stack similar to front contact 150. Back support 190, which may also be a glass, is formed over back contact 180.

Thin film cells may have two common types of front or back contacts. The first type of contact is a fully atmospheric pressure chemical vapor deposition (APCVD) coated fluorine-doped tin dioxide-based (F—SnO₂) stack where the barrier layer, TCO layer and buffer layer are all formed by APCVD. The TCO layer in that stack is a fluorine-doped SnO₂ layer. The second type of contact is a fully sputtered physical vapor deposition (PVD) TCO stack where the TCO layer is based on materials such as cadmium stannate (Cd₂SnO₄), indium tin oxide (ITO) and aluminum doped zinc oxide (ZAO). In the fully sputtered PVD TCO stack, the barrier layer, TCO layer and buffer layer are all formed by PVD. Each of these has both positive and negative attributes.

It is desirable to have a front contact for a photovoltaic device which mitigates the drawbacks associated with the TCO stacks of each of the fully APCVD coated devices and the fully sputtered PVD devices.

### BRIEF DESCRIPTION OF THE DRAWINGS

FIG. 1 is a cross-sectional view of a portion of a photovoltaic device.

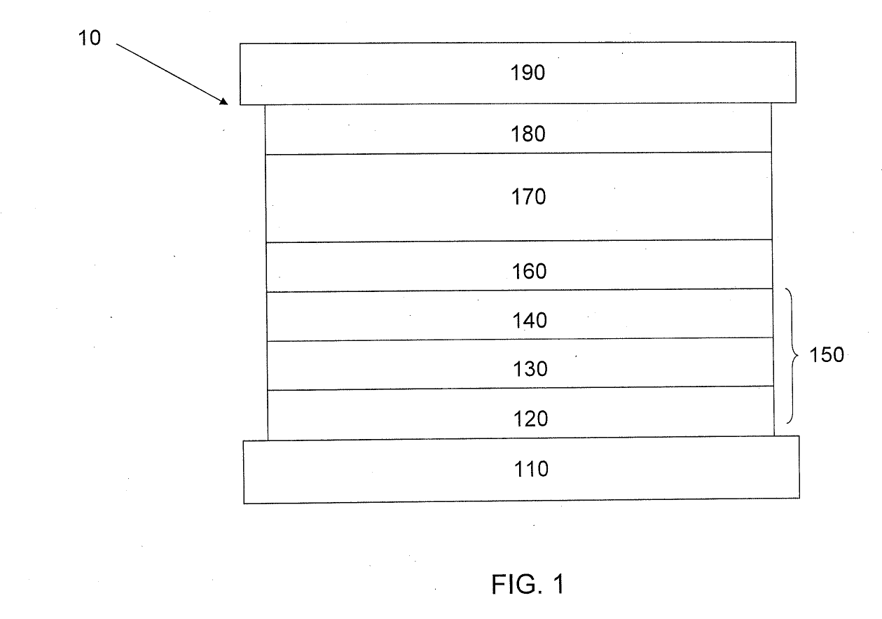

FIG. 2 is a cross-sectional view of a portion of a photovoltaic device in accordance with a disclosed embodiment.

FIG. 3 is a cross-sectional view of a portion of a photovoltaic device in accordance with the disclosed embodiment of FIG. 2.

FIG. 4 is a cross-sectional view of a portion of a photovoltaic device in accordance with another disclosed embodiment.

FIG. 5 is a cross-sectional view of a portion of a photovoltaic device in accordance with the disclosed embodiment of FIG. 4.

FIG. 6 is a cross-sectional view of a portion of a photovoltaic device in accordance with another disclosed embodiment.

FIG. 7 is a cross-sectional view of a portion of a photovoltaic device in accordance with the disclosed embodiment of FIG. 6.

FIG. 8 is a cross-sectional view of a portion of a photovoltaic device in accordance with another disclosed embodiment.

FIG. 9 is a cross-sectional view of a portion of a photovoltaic device in accordance with the disclosed embodiment of FIG. 8.

FIG. 10 is a cross-sectional view of a portion of a photovoltaic device in accordance with another disclosed embodiment.

FIG. 11 is a cross-sectional view of a portion of a photovoltaic device in accordance with the disclosed embodiment of FIG. 10.

FIG. 12 is a cross-sectional view of a portion of a photovoltaic device in accordance with another disclosed embodiment.

FIG. 13 is a cross-sectional view of a portion of a photovoltaic device in accordance with the disclosed embodiment of FIG. 12.

### DETAILED DESCRIPTION OF THE INVENTION

In the following detailed description, reference is made to the accompanying drawings, which form a part hereof, and in which is shown by way of illustration specific embodiments that may be practiced. It should be understood that like reference numbers represent like elements throughout the drawings. Embodiments are described in sufficient detail to enable those skilled in the art to make and use them, and it is to be understood that structural, material, electrical, and procedural changes may be made to the specific embodiments disclosed, only some of which are discussed in detail below.

Described herein is a photovoltaic device containing a multi-layered TCO stack hybrid contact, which may be, for example, a front contact for a photovoltaic device. The hybrid front contact is made up of a combination of APCVD layers and PVD layers. Such a hybrid front contact takes advantage of the beneficial characteristics of both APCVD and PVD coatings while also eliminating or mitigating their drawbacks. As a result, hybrid contacts offer unique attributes that are not attainable by either a fully APCVD TCO stack or a fully sputtered PVD TCO stack.

The fully APCVD coated stack provides many benefits. It can be used in an in-line APCVD process (with a glass float line for manufacturing a glass substrate or superstrate, e.g., 110, 190) that provides high deposition rates at a low cost. The stack may include an APCVD SiO₂ barrier layer 120, which is a superior sodium (Na) barrier and is a relatively thin barrier layer (˜25 nm) sufficient to control Na levels in device structures. The fully APCVD coated stack may include rough surfaces/interfaces throughout the stack that provide superior omni-directionality in sunny-side device reflection, which makes the appearance of fully APCVD-based devices less sensitive to viewing angles. Surface roughness can be quantified by an arithmetic mean value (Ra) and a root mean-square-average (Rq). For the surface of the buffer layer 140 of a fully APCVD-based TCO stack, Ra can range from about 5 nm to about 50 nm and Rq can range from about 27 nm to about 36 nm. Incorporation of a color suppression layer (not shown) further benefits the visual appearance of fully APCVD-based modules. The rough surfaces/interfaces and coating design for fully APCVD coated stacks reduce sunny-side reflection loss where the average reflection from the device side, excluding the reflection from the sunny-side glass surface (which is typically ˜4%) is only ˜1%. Additionally, the rough and faceted surface of the buffer layer 140 in the stack facilitates nucleation and growth of the cadmium sulfide (CdS) window layer 160.

The fully APCVD coated stack also provides some drawbacks. The TCO layer 130 in the fully APCVD coated stack is fluorine doped SnO₂, which is a TCO material with a relatively low carrier mobility. Due to contributions from both the absorption of light by free carriers, and carbon residue from the manufacturing process in the coating, a 9 ohm/sq fully APCVD coated stack typically has an average optical absorption (400-800 nm) in the range of 13-15%, even with low iron content glass as the substrate.

Similarly, the fully sputtered PVD TCO stack, where the TCO layer is made of Cd₂SnO₄, has many benefits. In the fully sputtered PVD TCO stack, the TCO layer 130 is one of the best-known TCO materials with both high carrier concentration and high mobility. A fully sputtered PVD TCO stack in a completed photovoltaic device can have a sheet resistance of 6 ohm/sq and an average optical absorption of ˜6%. Sheet resistance is a measurement of resistance of a thin film. Optical absorption is a measurement of the amount of light not passed through the layer. The sputtered barrier layer 120 (SiAlₓO_{y}) and buffer layer 140 (either SnOₓ or ZnSnₓO_{y}) are virtually absorption free in the visible spectrum. This offers fewer restrictions on stack design with little concerns over penalties from optical absorptions of the stack layers.

The fully sputtered PVD TCO stack also has some drawbacks. The sputtered barrier layer 120 generally has poor Na-blocking ability. This necessitates the use of a very thick SiAlOₓ barrier layer 120 (˜200 nm) in the stack. Further exacerbating the barrier-related issue are the low deposition rates of the sputtered barrier layer, due to an inherently low deposition rate of Si, even with adding Al into Si targets to increase the deposition rate by increasing conductivity. The sputtered PVD TCO stack has an amorphous structure, which is still highly optically absorbing and electrically resistive at its as-deposited state. The sputtered film must undergo a thermally activated phase transformation to become a transparent conductive oxide. The sputtered stack has a very smooth coating surface and interfaces between layers, which makes reflection strongly angle-dependent. Thus, modules with a fully sputtered PVD TCO stack tend to have uneven appearances. Compared to fully APCVD-based devices, which have higher Ra and Rq, sputtered PVD TCO stacks have Ra in the range of about 0.4 to about 2.8 nm and Rq in the range of about 0.6 nm to about 3.5 nm (when measuring the surface of the buffer layer). Furthermore, the devices having a fully PVD TCO stack generally have ˜2% higher reflection loss than the fully APCVD coated devices, largely due to “mirror-like” reflections of the smooth interfaces and surfaces in the fully sputtered PVD TCO stacks.

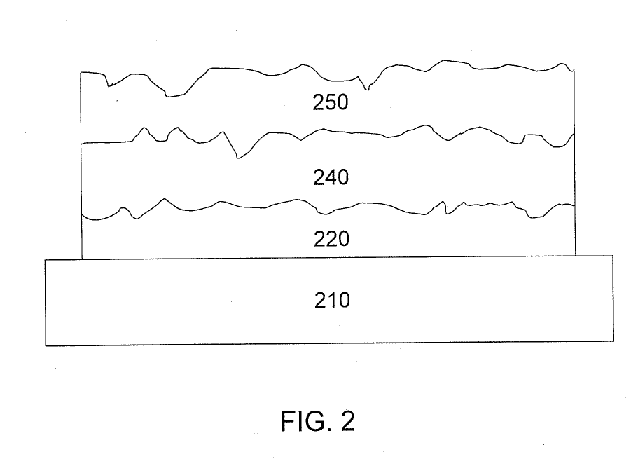

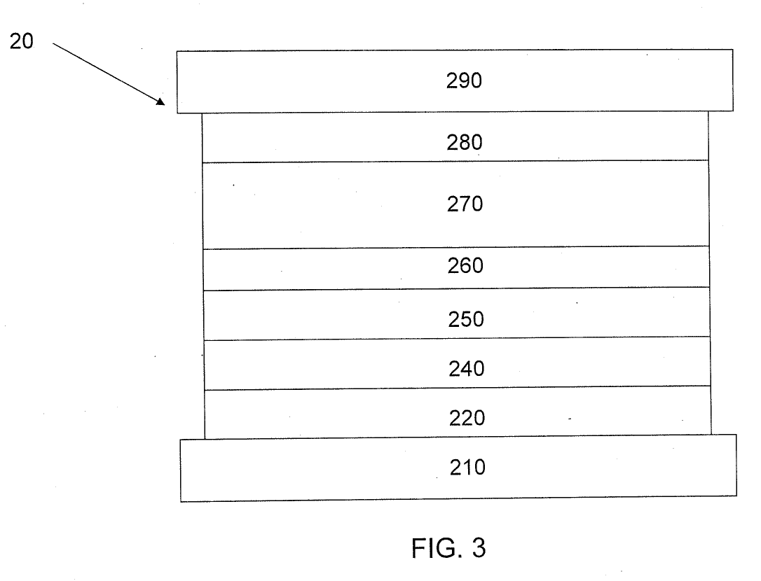

Referring to FIG. 2, a first embodiment is now described with reference to the manufacture of a hybrid front contact for use in a thin-film photovoltaic device. FIG. 2 is a cross-sectional view of a portion of a photovoltaic device 20 (FIG. 3). The hybrid front TCO contact consists of three functional layers 220, 240, 250. Layer 220 is an APCVD SiO₂ barrier layer that is deposited adjacent to glass substrate 210. Layer 220 not only serves as the barrier layer, but also provides a rough surface on which sputtered layers are subsequently deposited. Layer 240 is a sputtered TCO layer (e.g., Cd₂SnO₄). Layer 250 is a sputtered buffer layer (e.g., SnO₂). Layers 240 and 250 are formed conformably on the rough coating of layer 220 underneath and likely have rough surfaces.

While layers 240 and 250 in the hybrid front contact in FIG. 2 are illustrated to have high roughness, the level of roughness can differ from that of layer 220, depending on the growth conditions and previously performed heat treatments of the stack. It should be noted that the optical benefits of the hybrid front contact do not require the replication of the surface roughness of 220 by layers 240 and 250. This is because the diffuse scattering of the light by the hybrid front contact can be realized by the rough surface of layer 220 (or interface between layer 220 and 240). This is particularly true for other embodiments of the disclosure where the APCVD portion of a hybrid front contact can be a “stack” of more than one material (e.g. SnO₂, TiO₂, SiO₂, etc.). While not required, when buffer layer 250 does have a rough surface, it can have a surface roughness mean value (Ra) of about 5 nm to about 50 nm.

FIG. 3 shows photovoltaic device 20 with layers 220, 240 and 250 as described above, along with additional layers of the photovoltaic device. For simplicity, FIG. 3 shows layers 220, 240, 250 as having smooth surfaces, but it should be understood that the surfaces are as described above and depicted in FIG. 2. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also be a multi-layered stack. Back support 290 is formed over back contact 280.

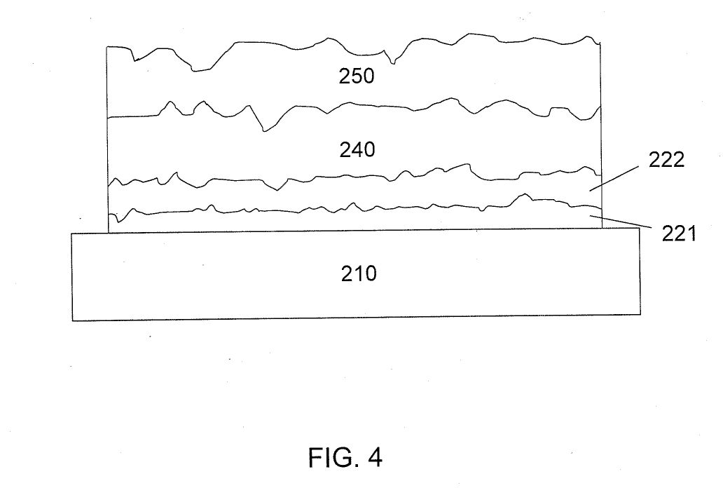

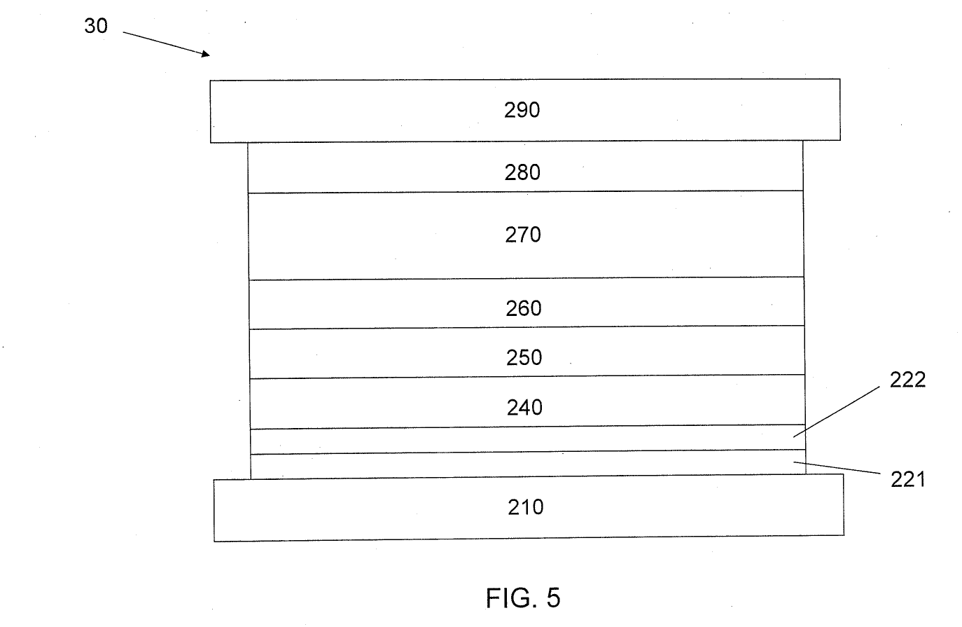

Referring to FIG. 4, a second embodiment is now described with reference to the manufacture of a hybrid front contact for use in a thin-film photovoltaic device. FIG. 4 is a cross-sectional view of a portion of a photovoltaic device 30 (FIG. 5). According to this embodiment, the APCVD barrier layer is a bi-layer 221,. 222 instead of the single layer 220, shown in FIG. 2. Thus, the barrier layer is made up of layers 221 and 222 formed over glass substrate 210. Layer 221 is a high refractive index APCVD layer (e.g., SnO₂) with a rough surface. Layer 222 is a low refractive index APCVD layer (e.g., SiO₂) with a rough surface. Layers 221 and 222 together serve not only as a Na barrier with a rough surface, but also as color suppression layers for further reduction in reflection loss due to the combination of the low and high refractive indexes. Layers 221 and 222 preferably should be optical materials with a high refractive index (i.e., refractive index of about 2.0 to about 2.4 at a wavelength of 589 nm) and a low refractive index (i.e., refractive index of about 1.45 to about 1.5 at a wavelength of 589 nm), respectively. The high refractive index material can include, but is not limited to, SiNₓ, SnO₂, TiO₂, Ta₂O₅ and Nb₂O₅. The low refractive index material can include, but is not limited to, SiO₂, SiAlₓO_{y} and Al₂O₃. Layer 240 is a sputtered TCO layer (e.g., Cd₂SnO₄). Layer 250 is a sputtered buffer layer (e.g., SnO₂). The sputtered buffer layer 250 of the hybrid front contact stack does not necessarily have Ra and Rq similar to a fully APCVD-based TCO stack. Again, the optical benefits of the hybrid front contact do not require the replication of surface roughness of APCVD layers by sputtered layers 240 and 250.

FIG. 5 shows photovoltaic device 30 with layers 221, 222, 240 and 250 as described above, along with additional layers of the photovoltaic device. Again, for simplicity, layers 221, 222, 240 and 250 in FIG. 5 are shown with smooth surfaces, but it should be understood that the surfaces are as described above and depicted in FIG. 4. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also be a multi-layered stack. Back support 290 is formed over back contact 280.

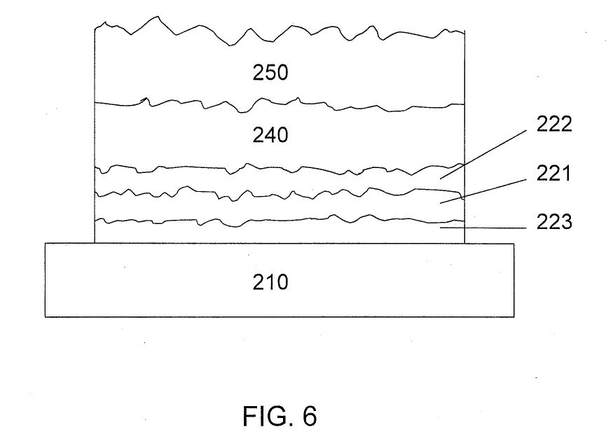

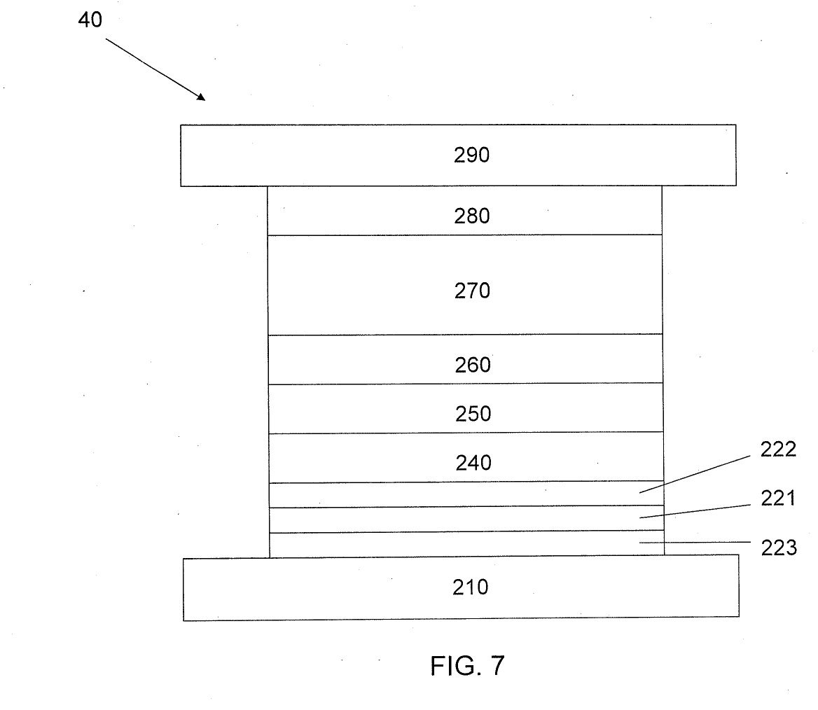

Referring to FIG. 6, a third embodiment is now described with reference to the manufacture of a hybrid front contact for use in a thin-film photovoltaic device. FIG. 6 is a cross-sectional view of a portion of a photovoltaic device 40 (FIG. 7). According to this embodiment, photovoltaic device 40 includes an additional low refractive index APCVD layer 223 underneath the APCVD bi-layer 221, 222. Layer 221 is a high refractive index APCVD layer (e.g., SnO₂) with a rough surface. Layer 222 is a low refractive index APCVD layer (e.g., SiO₂) with a rough surface. Layers 221 and 222 together serve not only as a Na barrier with a rough surface, but also as color suppression layers for further reduction in reflection loss. Layers 221 and 222 preferably should be optical materials with a high refractive index (i.e., refractive index of about 2.0 to about 2.4 at a wavelength of 589 nm) and a low refractive index (i.e., refractive index of about 1.45 to about 1.5 at a wavelength of 589 nm), respectively. The high refractive index material can include, but is not limited to, SiNₓ, SnO₂, TiO₂, Ta₂O₅ and Nb₂O₅. The low refractive index material can include, but is not limited to, SiO₂, SiAlₓO_{y} and Al₂O₃. Layer 223 can include, but is not limited to, SiO₂, SiAlₓO_{y} and Al₂O₃. In other words, this layer can be the same or a similar material as layer 222. The thickness of layer 223 can be from about 100 Å to about 2000 Å. The main function of layer 223 is to further improve the Na blocking ability of the stack and offers additional leverage on surface/interface roughness of the APCVD portion of the hybrid contact. Layer 240 is a sputtered TCO layer (e.g., Cd₂SnO₄). Layer 250 is a sputtered buffer layer (e.g., SnO₂). The sputtered buffer layer 250 of the hybrid front contact stack does not necessarily have Ra and Rq similar to a fully APCVD-based TCO stack. Again, the optical benefits of the hybrid front contact do not require the replication of surface roughness of APCVD layers by sputtered layers 240 and 250.

FIG. 7 shows photovoltaic device 40 with layers 221, 222, 223, 240 and 250 as described above, along with additional layers of the photovoltaic device. Again, for simplicity, layers 221, 222, 223, 240 and 250 in FIG. 7 are shown with smooth surfaces, but it should be understood that the surfaces are as described above and depicted in FIG. 6. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also be a multilayered stack. Back support 290 is formed over back contact 280.

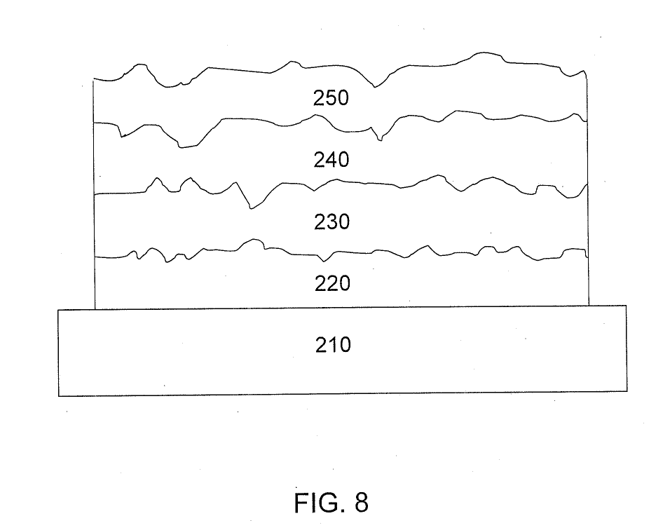

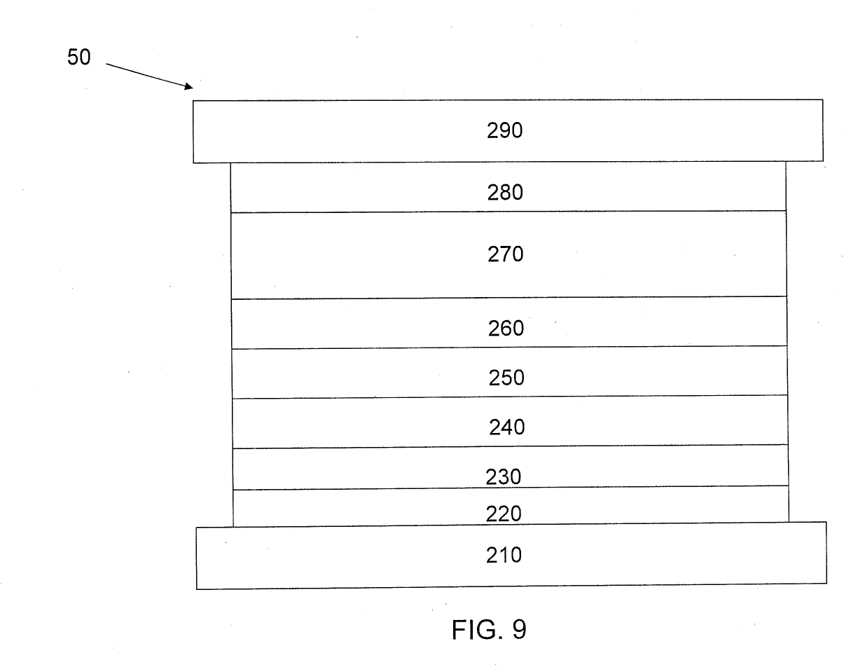

Referring to FIG. 8, a fourth embodiment is now described with reference to the manufacture of a hybrid front contact for use in a thin-film photovoltaic device. FIG. 8 is a cross-sectional view of a portion of a photovoltaic device 50 (FIG. 9). Layer 220 is an APCVD SiO₂ layer that is deposited over glass substrate 210. Layer 240 is a sputtered TCO layer (e.g., Cd₂SnO₄). According to this embodiment, a sputtered bond layer 230 is introduced to enhance adhesion between APCVD SiO₂ layer 220 and sputtered TCO layer 240. Sputtered bond layer 230 also provides additional reinforcement for Na blocking. Sputtered bond layer 230 can include, but is not limited to, SiO₂ or SiAlₓO_{y}. Layer 250 is a sputtered buffer layer (e.g., SnO₂). Layers 230, 240 and 250 are formed conformably on the rough coating of layer 220 underneath and have rough surfaces.

FIG. 9 shows photovoltaic device 50 with layers 220, 230, 240 and 250 as described above, along with additional layers of the photovoltaic device. Again, for simplicity, layers 220, 230, 240 and 250 in FIG. 9 are shown with smooth surfaces, but it should be understood that the surfaces are as described above and depicted in FIG. 8. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also be a multi-layered stack. Back support 290 is formed over back contact 280.

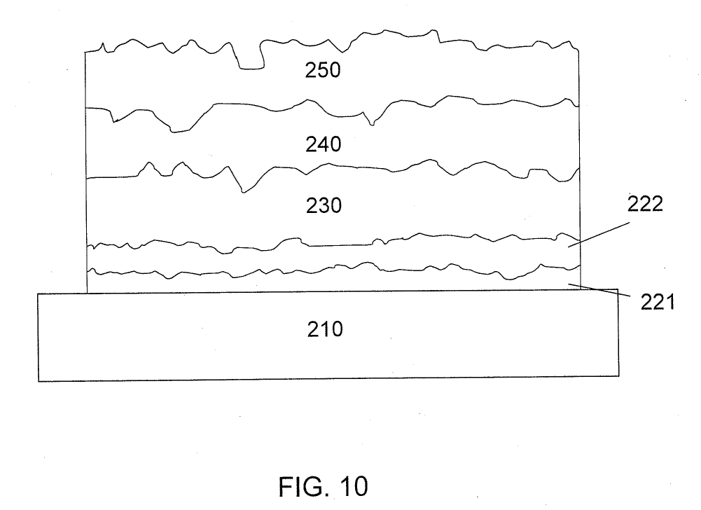

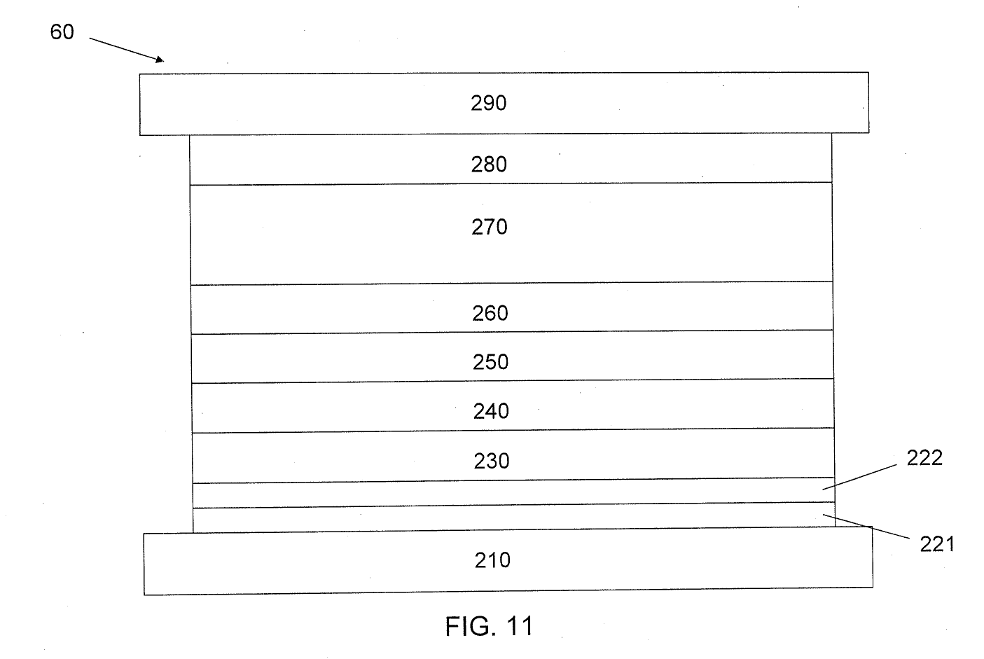

Referring to FIG. 10, a fifth embodiment is now described with reference to the manufacture of a hybrid front contact for use in a thin-film photovoltaic device. FIG. 10 is a cross-sectional view of a portion of a photovoltaic device 60 (FIG. 11). According to this embodiment, photovoltaic device 60 incorporates both an APCVD barrier bi-layer 221, 222 and a sputtered bond layer 230. The barrier layer is made up of layers 221 and 222 formed over glass substrate 210. Layer 221 is a high refractive index APCVD layer (e.g., SnO₂) with a rough surface. Layer 222 is a low refractive index APCVD layer (e.g., SiO₂) with a rough surface. Layers 221 and 222 together serve not only as a Na barrier with a rough surface, but also as color suppression layers for further reduction in reflection loss. Layers 221 and 222 preferably should be optical materials with a high refractive index (i.e., refractive index of about 2.0 to about 2.4 at a wavelength of 589 nm) and a low refractive index (i.e., refractive index of about 1.45 to about 1.5 at a wavelength of 589 nm), respectively. The high index material can include, but is not limited to, SiNₓ, SnO₂, TiO₂, Ta₂O₅ and Nb₂O₅. The low index material can include, but is not limited to, SiO₂, SiAlₓO_{y} and Al₂O₃. TCO layer 240 is a sputtered TCO layer (e.g., Cd₂SnO₄). Sputtered bond layer 230 is introduced to enhance adhesion between low refractive index APCVD layer 222 and sputtered TCO layer 240, and provides additional reinforcement for Na blocking. Sputtered bond layer 230 can include, but is not limited to, SiO₂ or SiAlₓO_{y}. Layer 250 is a sputtered buffer layer (e.g., SnO₂). Layers 230, 240 and 250 are formed conformably on the rough coating of layer 222 underneath and have rough surfaces.

FIG. 11 shows photovoltaic device 60 with layers 221, 222, 230, 240 and 250 as described above, along with additional layers of the photovoltaic device. Again, for simplicity, layers 221, 222, 230, 240 and 250 in FIG. 11 are shown with smooth surfaces, but it should be understood that the surfaces are as described above and depicted in FIG. 10. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also a multi-layered stack. Back support 290 is formed over back contact 280.

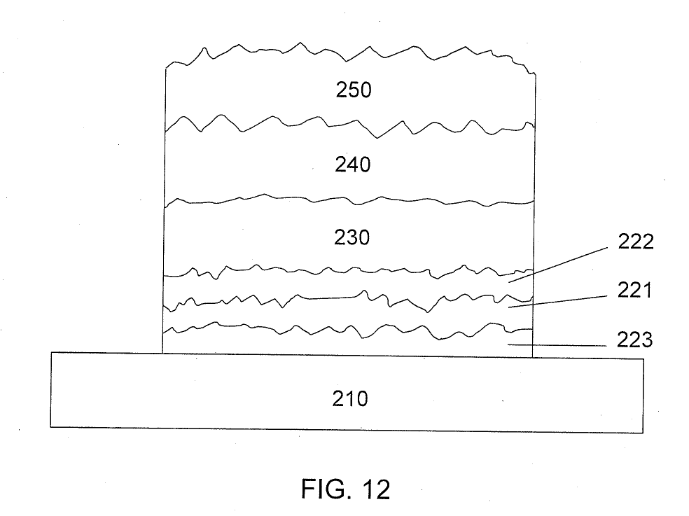

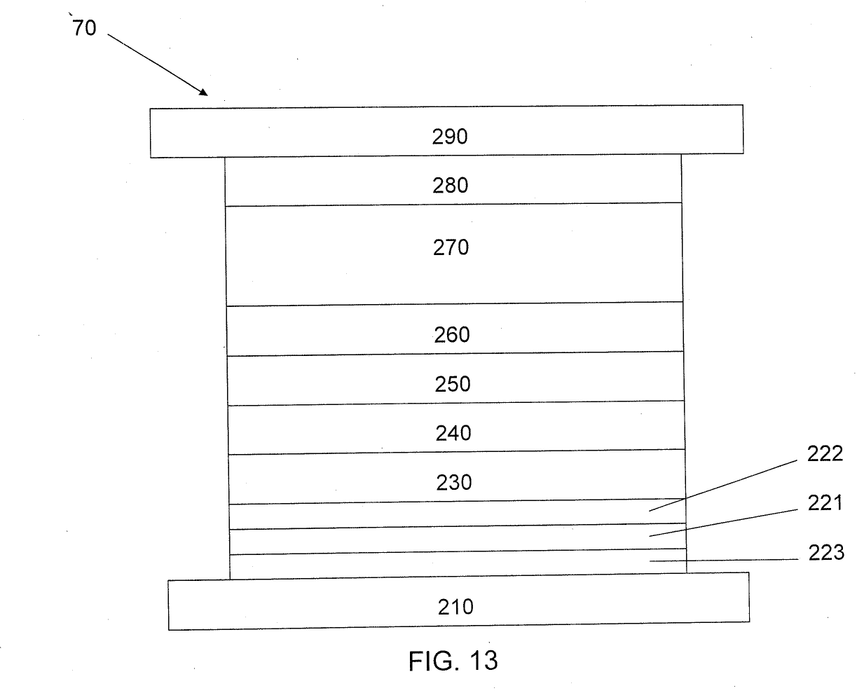

Referring to FIG. 12, a sixth embodiment is now described with reference to the manufacture of a hybrid front contact for use in a thin-film photovoltaic device. FIG. 12 is a cross-sectional view of a portion of a photovoltaic device 70 (FIG. 13). According to this embodiment, photovoltaic device 70 includes an additional low index APCVD layer 223 underneath the APCVD bi-layer 221, 222. Layer 221 is a high refractive index APCVD layer (e.g., SnO₂) with a rough surface. Layer 222 is a low refractive index APCVD layer (e.g., SiO₂) with a rough surface. Layers 221 and 222 together serve not only as a Na barrier with a rough surface, but also as color suppression layers for further reduction in reflection loss. Layers 221 and 222 preferably should be optical materials with a high refractive index (i.e., refractive index of about 2.0 to about 2.4 at a wavelength of 589 nm) and a low refractive index (i.e., refractive index of about 1.45 to about 1.5 at a wavelength of 589 nm), respectively. The high index material can include, but is not limited to, SiNₓ, SnO₂, TiO₂, Ta₂O₅ and Nb₂O₅. The low index material can include, but is not limited to, SiO₂, SiAlₓO_{y} and Al₂O₃. Layer 223 can include, but is not limited to, SiO₂, SiAlₓO_{y} and Al₂O₃. In other words, this layer can be the same or a similar material as layer 222. The thickness of layer 223 can be from about 100 Å to about 2000 Å. The main function of layer 223 is to further improve the Na blocking ability of the stack and offers additional leverage on surface/interface roughness of the APCVD portion of the hybrid contact. TCO layer 240 is a sputtered TCO layer (e.g., Cd₂SnO₄). Sputtered bond layer 230 is introduced to enhance adhesion between low refractive index APCVD layer 222 and sputtered TCO layer 240, and provides additional reinforcement for Na blocking. Sputtered bond layer 230 can include, but is not limited to, SiO₂ or SiAlₓO_{y}. Layer 250 is a sputtered buffer layer (e.g., SnO₂). Layers 230, 240 and 250 are formed conformably on the rough coating of layer 222 underneath and have rough surfaces.

FIG. 13 shows photovoltaic device 70 with layers 221, 222, 223, 230, 240 and 250 as described above, along with additional layers of the photovoltaic device. Again, for simplicity, layers 221, 222, 223, 230, 240 and 250 in FIG. 13 are shown with smooth surfaces, but it should be understood that the surfaces are as described above and depicted in FIG. 12. Window layer 260, which is a semiconductor layer, is formed over buffer layer 250. Absorber layer 270, which is also a semiconductor layer, is formed over window layer 260. Back contact 280 is formed over absorber layer 270. Back contact 280 may also a multi-layered stack. Back support 290 is formed over back contact 280.

In each of the embodiments discussed above the particular layers may be formed of the following materials and have the following characteristics. Barrier layer 220 may be an APCVD layer formed of SiO₂ and may have a thickness of about 100 Å to about 1000 Å. High refractive index layer 221 may be an APCVD layer formed of one of SiN_{X}, SnO₂, TiO₂, Ta₂O₅ and Nb₂O₅ and may have a thickness of about 100 Å to about 1000 Å. Low refractive index layer 222 may be an APCVD layer formed of one of SiO₂, SiAlₓO_{y} and Al₂O₃ and may have a thickness of about 100 Å to about 1000 Å. Layer 223 may be an APCVD layer formed of one of SiO₂, SiAlₓO_{y} and Al₂O₃. Bond layer 230 may be formed by physical vapor deposition, may be formed of one of SiO₂ and SiAlₓO_{y} and may have a thickness of about 100 Å to about 1000 Å. Sputtered TCO layer 240 may be formed of one of F—SnO₂, Cd₂SnO₄, ITO, CIO and ZAO and may have a thickness of about 500 Å to about 5000 Å. Sputtered buffer layer 250 may be formed of one of SnO₂, ZnO, In₂O₃ and ZnSnₓO_{y} and may have a thickness of about 50 Å to about 2000 Å.

The hybrid front contact provides many benefits. The barrier to mobile ions is provided by the APCVD SiO₂ layer or a bi-layer of SnO₂/SiO₂. These layers have proven to be superior in limiting migration of mobile ions, such as Na, from the glass substrate. Due to the improved blocking ability of the hybrid front contact, it also allows for a wider processing window for variables in semiconductor deposition processes, such as temperature profile, deposition rate, thickness of the semiconductor, and speed of the substrate through the process.

The interfacial roughness of the APCVD barrier layer in the various described embodiments also provides less reflection loss. Tests consistently show that the fully APCVD devices have 1.5-2% less average reflection loss than those based on fully sputtered PVD TCO stacks. The benefits from the fully APCVD devices result, in large part, from the interfacial roughness. This can be shown through tests on sunnyside reflections. Test results suggest that the low reflection loss for fully APCVD devices mainly results from the interfacial roughness of the APCVD stack. The improvement in TCO characteristics would further contribute to increased efficiencies.

Photovoltaic devices having hybrid contacts have improved reliability for several reasons. A better Na barrier in a hybrid front contact leads to decreased levels of impurities in the device structures. The rough buffer layer 250 surface provides a stronger interface between the buffer layer and CdS window layer, which enhances the resistance to interfacial debonding. The manufacturing of the hybrid front contact also largely eliminates the need for a thick sputtered SiAlₓO_{y} barrier layer, which has very low deposition rates. This helps reduce the manufacturing costs. The hybrid front contact of the disclosed embodiments also reduces reflection loss, which leads to a more efficient photovoltaic device. There is an increased manufacturing yield due to a less limited processing window. Additionally, photovoltaic devices based on a hybrid front contact have a similar appearance to fully APCVD coated stacks and thus generally look better due to reduced magnitude and superior omni-directionality of sunny-side device reflection.

While disclosed embodiments have been described in detail, it should be readily understood that the invention is not limited to the disclosed embodiments. Rather, the disclosed embodiments can be modified to incorporate any number of variations, alterations, substitutions or equivalent arrangements not heretofore described.

1. A contact for a photovoltaic device, comprising:
a transparent conductive oxide stack of the photovoltaic device, wherein a first portion of the transparent conductive oxide stack is formed by atmospheric pressure chemical vapor deposition and a second portion of the transparent conductive oxide stack is formed by physical vapor deposition.

2. The contact of claim 1, wherein the transparent conductive oxide stack comprises a barrier layer, a transparent conductive oxide layer and a buffer layer.

3. The contact of claim 2, wherein the barrier layer is formed by atmospheric pressure chemical vapor deposition and the transparent conductive oxide layer and buffer layer are formed by physical vapor deposition.

4-5. (canceled)

6. The contact of claim 2, wherein the transparent conductive oxide layer comprises a material selected from the group consisting of F—SnO₂, Cd₂SnO₄, ITO, CIO and ZAO.

7. The contact of claim 2, wherein the buffer layer comprises a material selected from the group consisting of SnO₂, ZnO, In₂O₃ and ZnSnₓO_{y}.

8. The contact of claim 2, wherein the buffer layer has a surface roughness mean value of about 5 nm to about 50 nm.

9. The contact of claim 2, wherein the barrier layer comprises a first material with a refractive index of about 1.45 to about 1.50 formed over a second material with a refractive index of about 2.0 to about 2.4.

10. The contact of claim 9, wherein first material of the barrier layer is selected from the group consisting of SiO₂, SiAlₓO_{y} and Al₂O₃.

11. The contact of claim 9, wherein the second material of the barrier layer is selected from the group consisting of SiN_{X}, SnO₂, TiO₂, Ta₂O₅ and Nb₂O₅.

12. The contact of claim 1, further comprising a bond layer formed over the first portion of the transparent conductive oxide stack, wherein the bond layer is formed by physical vapor deposition.

13. The contact of claim 12, wherein the bond layer comprises a material selected from the group consisting of SiO₂ and SiAlₓO_{y}.

14. The contact of claim 9, further comprising a bond layer formed over the barrier layer, wherein the bond layer is formed by physical vapor deposition.

15. The contact of claim 14, wherein the bond layer comprises a material selected from the group consisting of SiO₂ and SiAlₓO_{y}.

16. The contact of claim 2, wherein the barrier layer has a thickness of about 100 Å to about 1000 Å.

17. The contact of claim 9, wherein the first material of the barrier layer has a thickness of about 100 Å to about 1000 Å and the second material of the barrier layer has at thickness of about 100 Å to about 1000 Å.

18. The contact of claim 2, wherein the transparent conductive oxide layer has a thickness of about 500 Å to about 5000 Å.

19. The contact of claim 2, wherein the buffer layer has a thickness of about 50 Å to about 2000 Å.

20. The contact of claim 12, wherein the bond layer has a thickness of about 100 Å to about 1000 Å.

21. The contact of claim 9, further comprising an APCVD-deposited material underneath the barrier layer, wherein the APCVD-deposited material is selected from the group consisting of SiO₂, SiAlₓO_{y} and Al₂O₃.

22. A photovoltaic device comprising:
a substrate of the photovoltaic device;
a contact, provided over the substrate, comprising:
a barrier layer formed by atmospheric pressure chemical vapor deposition;
a transparent conductive oxide layer formed over the barrier layer, the transparent conductive oxide layer being formed by physical vapor deposition; and
a buffer layer formed over the transparent conductive oxide layer, the buffer layer being formed by physical vapor deposition.

23-24. (canceled)

25. The photovoltaic device of claim 22, wherein the transparent conductive oxide layer comprises a material selected from the group consisting of F—SnO₂, Cd₂SnO₄, ITO, CIO and ZAO.

26. The photovoltaic device of claim 22, wherein the buffer layer comprises a material selected from the group consisting of SnO₂, ZnO, In₂O₃ and ZnSnₓO_{y}.

27. The photovoltaic device of claim 22, wherein the barrier layer is formed in contact with the substrate.

28. The photovoltaic device of claim 22, wherein the barrier layer has a thickness of about 100 Å to about 1000 Å.

29. The photovoltaic device of claim 22, wherein the barrier layer comprises a first material with a refractive index of about 1.45 to about 1.50 formed over a second material with a refractive index of about 2.0 to about 2.4.

30. The photovoltaic device of claim 29, wherein the first material of the barrier layer is selected from the group consisting of SiO₂, SiAlₓO_{y} and Al₂O₃.

31. The photovoltaic device of claim 29, wherein the second material of the barrier layer is selected from the group consisting of SiNₓ, SnO₂, TiO₂, Ta₂O₅ and Nb₂O₅.

32. The photovoltaic device of claim 29, wherein the first material of the barrier layer has a thickness of about 100 Å to about 1000 Å and the second material of the barrier layer has at thickness of about 100 Å to about 1000 Å.

33. The photovoltaic device of claim 22, wherein the transparent conductive oxide layer has a thickness of about 500 Å to about 5000 Å.

34. The photovoltaic device of claim 22, wherein the buffer layer has a thickness of about 50 Å to about 2000 Å.

35. The photovoltaic device of claim 22, further comprising a bond layer formed over the barrier layer, wherein the bond layer is formed by physical vapor deposition.

36. The photovoltaic device of claim 35, wherein the bond layer comprises a material selected from the group consisting of SiO₂ and SiAlₓO_{y}.

37. The photovoltaic device of claim 35, wherein the bond layer is about 100 Å to about 1000 Å.

38. The photovoltaic device of claim 29, further comprising a bond layer formed over the barrier layer, wherein the bond layer is formed by physical vapor deposition.

39. The photovoltaic device of claim 38, wherein the bond layer comprises a material selected from the group consisting of SiO₂ and SiAlₓO_{y}.

40. The photovoltaic device of claim 38, wherein the bond layer has a thickness of about 100 Å to about 1000 Å.

41. The photovoltaic device of claim 22, further comprising:
a window layer formed over the buffer layer;
an absorber layer formed over the window layer;
a back contact formed over the absorber layer; and
a back support formed over the back contact.

42-44. (canceled)

45. The photovoltaic device of claim 22, wherein the buffer layer has a surface roughness mean value of about 5 nm to about 50 nm.

46. The photovoltaic device of claim 29, further comprising an APCVD-deposited material underneath the barrier layer, wherein the APCVD-deposited material is selected from the group consisting of SiO₂, SiAlₓO_{y} and Al₂O₃.

47. A method of forming a photovoltaic device comprising the steps of:
forming a barrier layer over a glass substrate of the photovoltaic device, wherein the barrier layer is formed by atmospheric pressure chemical vapor deposition;
forming a transparent conductive oxide layer over the barrier layer, wherein the transparent conductive oxide layer is formed by physical vapor deposition; and
forming a buffer layer over the transparent conductive oxide layer, wherein the buffer layer is formed by physical vapor deposition.

48. The method of claim 47, further comprising the steps of:
forming a window layer over the buffer layer;
forming an absorber layer over the window layer;
forming a back contact over the absorber layer; and
forming a back support over the back contact.

49. (canceled)

50. The method of claim 47, wherein the barrier layer has a thickness of about 100 Å to about 1000 Å.

51. (canceled)

52. The method of claim 47, wherein the transparent conductive oxide layer has a thickness of about 500 Å to about 5000 Å.

53. (canceled)

54. The method of claim 47, wherein the buffer layer has a thickness of about 50 Å to about 2000 Å.

55. The method of claim 47, wherein forming the barrier layer comprises forming a first material with a refractive index of about 1.45 to about 1.50 over a second material with a refractive index of about 2.0 to about 2.4.

56. The method of claim 55, wherein the first material is selected from the group consisting of SiO₂, SiAlₓO_{y} and Al₂O₃.

57. The method of claim 55, wherein the second material is selected from the group consisting of SiNₓ, SnO₂, TiO₂, Ta₂O₅ and Nb₂O₅.

58. The method of claim 55, wherein the first material of the barrier layer has a thickness of about 100 Å to about 1000 Å and the second material of the barrier layer has at thickness of about 100 Å to about 1000 Å.

59. The method of claim 47, further comprising forming a bond layer over the barrier layer, wherein the bond layer is formed by physical vapor deposition.

60. The method of claim 59, wherein the bond layer comprises a material selected from the group consisting of SiO₂ and SiAlOₓ.

61. The method of claim 59, wherein the bond layer has a thickness of about 100 Å to about 1000 Å.

62-64. (canceled)

65. The method of claim 47, wherein the buffer layer is formed to have a surface roughness mean value of about 5 nm to about 50 nm.

66. The method of claim 55, further comprising forming a bond layer over the barrier layer, wherein the bond layer is formed by physical vapor deposition.

67. The method of claim 66, wherein the bond layer comprises a material selected from the group consisting of SiO₂ and SiAlₓO_{y}.

68. The method of claim 66, wherein the bond layer has a thickness of about 100 to about 1000 Å.

69. The method of claim 55, further comprising forming an APCVD-deposited material underneath the barrier layer, wherein the APCVD-deposited material is selected from the group consisting of SiO₂, SiAlₓO_{y} and Al₂O₃.

70. A method of forming a contact for a photovoltaic device comprising the steps of:
forming a transparent conductive oxide stack for a photovoltaic device, wherein a first portion of the transparent conductive oxide stack is formed by atmospheric pressure chemical vapor deposition and a second portion of the transparent conductive oxide stack is formed by physical vapor deposition.

71. The method of claim 70, wherein the transparent conductive oxide stack comprises a barrier layer, a transparent conductive oxide layer and a buffer layer.

72. The method of claim 71, wherein the barrier layer is formed by atmospheric pressure chemical vapor deposition and the transparent conductive oxide layer and the buffer layer are formed by physical vapor deposition.

73. (canceled)
